(19) United States
(12) Patent Application Publication
(10) Pub. No.: US 2025/0380838 A1
(43) Pub. Date: Dec. 18, 2025

(54) FOOD PROCESSOR

(71) Applicant: Breville Pty Limited, Alexandria, NSW (AU)

(72) Inventors: Lochana Subasekara WIDANAGAMAGE DON, Alexandria (AU); Con PSAROLOGOS, Alexandria (AU); Joshua Lyndon COOPER, Alexandria (AU)

(21) Appl. No.: 18/878,294

(22) PCT Filed: Jun. 28, 2023
(86) PCT No.: PCT/AU2023/050593

§ 371 Date: Dec. 23, 2024

(30) Foreign Application Priority Data
Jun. 30, 2022 (AU) 2022901849

(51) Int. Cl. A47J 43/07; A47J 43/046; G02B 5/20

(52) U.S. Cl. CPC A47J 43/0777; A47J 43/046; A47J 43/0727; A47J 43/0794; G02B 5/208

(57) ABSTRACT

A food processor (100) including: a base (102) having a mechanism (118) that is operated using electrical power to cause processing of food; a vessel (104) removably mounted on the base (102) and including a bottom wall (108), a side wall (110) extending upwardly from the bottom wall (108) to a rim (112) so as to provide a space (114) to receive the food to be processed, with the rim (112) surrounding an opening (116) to the space; a lid (106) removable coupled to the rim (112) so as to at least partially close the opening (116); and an interlock system (120) operatively associated with the mechanism (118) to cause operation of the mechanism (118), the interlock system (120) including: a transmission coil (122) mounted in the base (102) and a receiver coil (124) mounted in the vessel (104), the transmission and receiver coils (122, 124) being configured to allow inductive transmission of power from the transmission coil (122) to the receiver coil (124); a switch (200) located on the vessel (104), operable between a first state and a second state, the switch (200) being biased toward the first state; and an optical transmitter (126) in the vessel and an optical receiver (128) in the base, the optical transmitter (126) being adapted to emit an activation signal when the switch (200) is in the second state, and the optical receiver (128) being configured to cause operation of the mechanism (118) when the activation signal is received by the optical receiver (126).

### RELATED APPLICATIONS

This application claims convention priority from Australian Provisional Patent Application No. 2022901849, the contents of which are incorporated herein in their entirety by reference thereto.

### FIELD

This application relates to a food processor.

### BACKGROUND

Safety interlock systems are an important feature of food processors, due to the relatively large opening provided by their vessels, and the potential for serious harm if the food processor was operating while the space within the vessel is accessible. Previous systems for providing interlock systems have been contemplated in PCT Publication Nos. WO 2012/075525 A1 and WO 2020/191437 A1, which are included in this specification in their entirety by reference thereto.

With increasingly complex interlock systems, user error can be a major detriment to the usability of a device, particularly when the systems require a number of electrical, optical, and mechanical systems to be connected to provide functionality of the food processor.

### SUMMARY

It is an object of the present invention to at least substantially address one or more of the above-mentioned disadvantages, or at least provide a useful alternative to the above discussed food processors.

The present invention provides a food processor including:
a base having a mechanism that is operated using electrical power to cause processing of food;
a vessel removably mounted on the base and including a bottom wall, a side wall extending upwardly from the bottom wall to a rim so as to provide a space to receive the food to be processed, with the rim surrounding an opening to the space;
a lid removable coupled to the rim so as to at least partially close the opening; and
an interlock system operatively associated with the mechanism to cause operation of the mechanism, the interlock system including:
   a transmission coil mounted in the base and a receiver coil mounted in the vessel, the transmission and receiver coils being configured to allow inductive transmission of power from the transmission coil to the receiver coil;
   a switch located on the vessel, operable between a first state and a second state, the switch being biased toward the first state; and
   an optical transmitter in the vessel and an optical receiver in the base, the optical transmitter being adapted to emit an activation signal when the switch is in the second state and power is received by the receiver coil, and the optical receiver being configured to cause operation of the mechanism when the activation signal is received by the optical receiver.

Preferably, the food processor further includes a visible indicator adapted to provide a visual indication when the switch is in the first state and power is received by the receiver coil.

Preferably, the food processor further includes an illumination device embedded in the vessel, the illumination device being connected to a common contact of the switch such that the illumination device provides an illumination of the vessel irrespective of the state of the switch.

Preferably, the lid includes a conductive pad, and wherein the optical transmitter is not operable unless the conductive pad of the lid completes a connection when coupled to the rim.

Preferably, the lid includes a cam that is engageable with the switch to move the switch to the second state when the lid is coupled to the rim.

Preferably, the lid includes a feed tube having a linkage that is moveable between a free position and an engaged position, wherein, in the engaged position, the linkage moves the switch to the second state, and
wherein the food processor further includes a pusher device configured to be operable inside the feed tube, the pusher device including a pusher cam that is engageable with the linkage to move the linkage to the engaged position when the pusher device is located in the feed tube, and thereby move the switch to the second state.

### BRIEF DESCRIPTION OF THE DRAWING

Preferred embodiments of the present invention will now be described by way of example, with reference to the accompanying drawings, wherein:

FIG. 1 is an isometric view of a food processor according to a preferred embodiment of the invention.

FIG. 2 is a schematic diagram of the food processor of FIG. 1.

FIG. 3 is an isometric view of a vessel of the food processor of FIG. 1.

FIG. 4 is an isometric view of a switch of the food processor of FIG. 1.

FIG. 5 is a front section view of the switch of FIG. 4.

FIG. 6 is a right section view of the switch of FIG. 4.

FIG. 7 is a left section view of the switch of FIG. 4.

FIG. 8 is an isometric view of a switch of the food processor of FIG. 1, according to a second embodiment.

FIG. 9 is an exploded isometric view of the food processor of FIG. 1.

### DETAILED DESCRIPTION

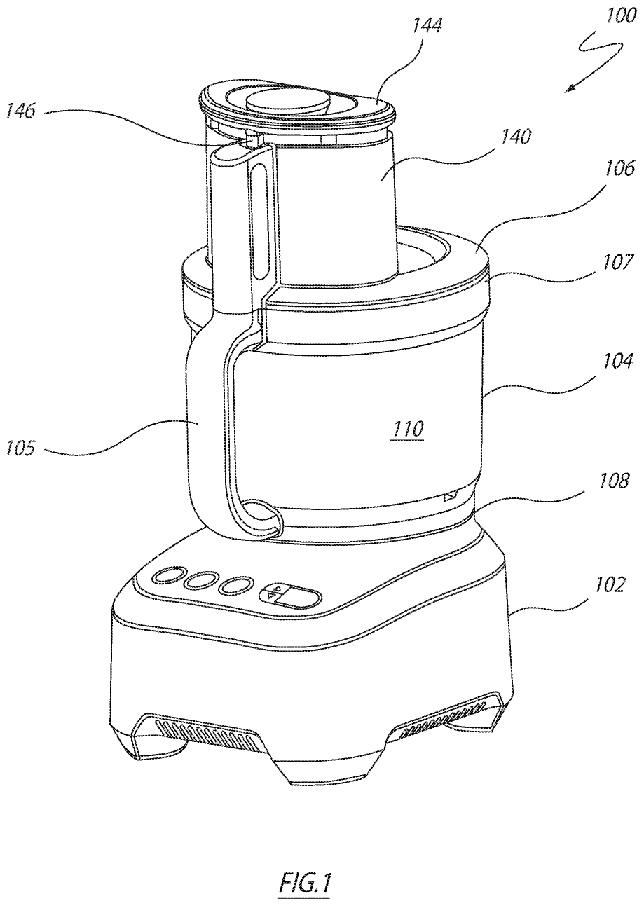

FIG. 1 shows a food processor 100 according to a preferred embodiment of the invention. The food processor 100 includes a base 102, a vessel 104, and a lid 106. The vessel 104 is removably mounted on the base 102. As seen in FIG. 3, the vessel 104 includes a bottom wall 108, a side wall 110 extending upwardly from the bottom wall 108 to a rim 112 so as to provide a space 114 to receive the food to be processed. The rim 112 surrounds an opening 116 to the space 114. The lid 106 has a lid base 107 and is removably coupled to the rim 112 with the lid base 107 so as to close the opening 116.

The base 102 houses a mechanism 118 that is operated using electrical power to cause processing of food contained in the space 114. The mechanism 118 may be a motor, for example. The motor may be coupled to a shaft extending through the bottom wall into the space to drive the shaft about an axis and, in turn, drive a blade system coupled to the shaft. In an alternative embodiment, the mechanism may be a heating element for providing heat to the food to be processed. Other embodiments may include both a motor and a heating element.

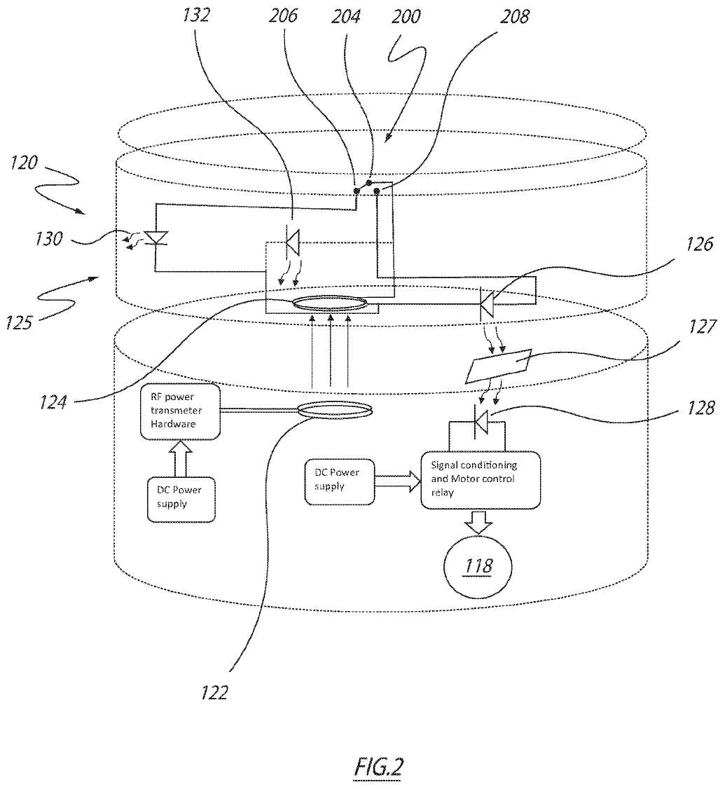

As shown in FIG. 2, the food processor 100 further includes an interlock system 120 that is operatively associated with the mechanism 118 to cause operation of the mechanism 118. The interlock system 120 includes a transmission coil 122 mounted in the base 102 and a receiver coil 124 mounted in the vessel 104. The transmission and receiver coils 122, 124 are configured to allow inductive transmission of power from the transmission coil 122 to the receiver coil 124. The receiver coil 124 powers a circuit 125 in the vessel 104, that includes a switch 200 that is also located on the vessel 104. The switch 200 is operable between a first state and a second state. The switch 200 includes a bias element 202 that biases the switch 200 toward the first state. The switch includes a common terminal 204, that is connected to a first side of the receiver coil 124, and a first terminal 206 establishes a connection to a second side of the receiver coil 124. When the switch 200 is in the first state, the switch 200 establishes an electrical connection between the common terminal 204 and the first terminal 206. The switch 200 further includes a second terminal 208 connected to a second side of the receiver coil 122. When the switch 200 is in the second state, the switch 200 establishes an electrical connection between the common terminal 204 and the second terminal 208.

The interlock system 120 further includes an optical transmitter 126 in the vessel 104 and an optical receiver 128 in the base 102. The term “optical” in this specification means related to electromagnetic radiation in the visible light spectrum, or adjacent thereto, for example including infrared and ultraviolet electromagnetic radiation. The optical transmitter 126 is connected to the circuit 125, preferably between the second terminal 208 of the switch 200 and the receiver coil 124, such that when the switch 200 is in the second state, an electric circuit including the receiver coil 124 is completed through the optical transmitter 126, causing the optical transmitter 126 to emit an activation signal when power is transmitted from the transmitter coil 122 to the receiver coil 124. The optical receiver 128, for example a phototransistor, is located to receive the activation signal from the optical transmitter when the vessel 104 is appropriately connected to the base 102. The optical receiver 128 is also configured to cause operation of the mechanism 118 when the activation signal is received by the optical receiver 128.

In one embodiment, the interlock system further includes a filter 127 between the optical transmitter 126 and the optical receiver 128. The filter 127 is preferably located in the base 102. More preferably, the filter 127 is located closer to or adjacent the optical receiver 128. The filter 127 is adapted to filter electromagnetic radiation received by the optical receiver 128 such that wavelengths substantially different to those emitted by the optical transmitter 126 are attenuated. In a preferred embodiment, the optical transmitter 126 emits radiation with a wavelength of about 900 nm, in another embodiment the wavelength is about 940 nm. The filter preferably attenuates wavelengths outside of a band of 900 nm to 980 nm. In this way, the signal to noise ratio of the optical receiver 128 is improved by filtering other ambient signal sources, such as natural light, or light from light sources other than the optical transmitter 126.

Other embodiments are possible in which the optical transmitter 126 is not an LED, or other light source, but operates on different parts of the electromagnetic spectrum. Importantly, however, the filter 127 operates to attenuate wavelengths that are substantially different to those emitted by the optical transmitter 126.

The interlock system 120 further includes a visible indicator 130, for example a visible light LED, connected to the circuit 125, preferably between the first terminal 206 and the receiver coil 124, so that when the switch 200 is in the first state, an electric circuit including the receiver coil 124 is completed through the visible indicator 130, causing the visible indicator 130 to provide a visual indication that the device is ready to receive the pusher 144. Preferably, the visible indicator 130 is located close to the rim 112 of the vessel 104, so as to be easily seen by a user. In an alternative embodiment, the indicator 130 is absent. Thus, instead of a two state switch, a single state switch is used since terminal 206 is not connected to anything.

In another embodiment, the food processor includes an illumination device 132 embedded in the vessel 104. For example, the illumination device 132 may include a series of visible light LEDs forming a ring adjacent to the rim 122 of the vessel 104. The illumination device 132 is connected to the circuit 125, preferably between the common terminal 204 and the receiver coil 124 so that an electric circuit including the receiver coil 124 is completed through the illumination device 132, causing the illumination device 132 to provide illumination of the vessel 104 when power is transmitted from the transmitter coil 122 to the receiver coil 124, but irrespective of the state of the switch 200.

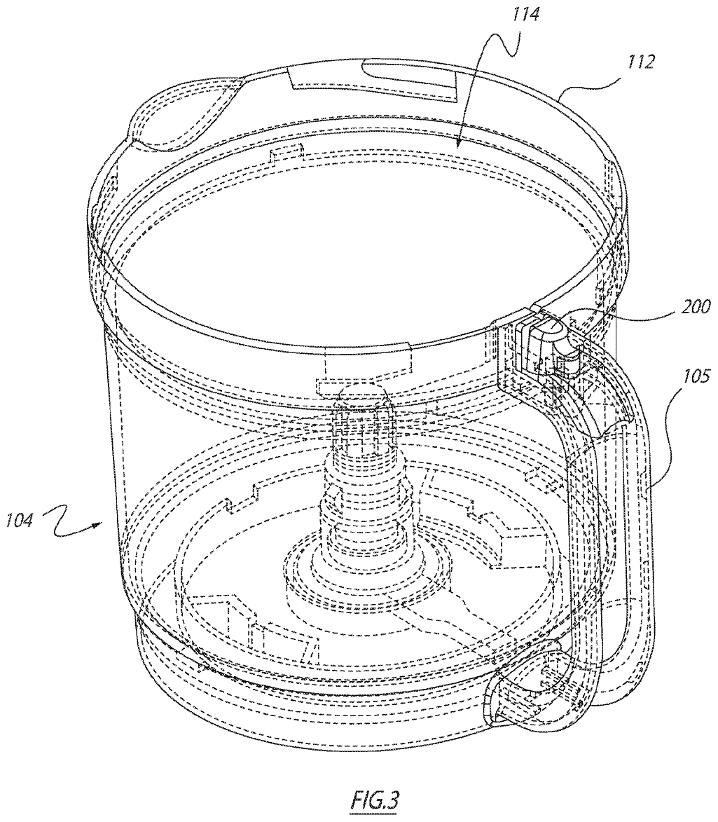

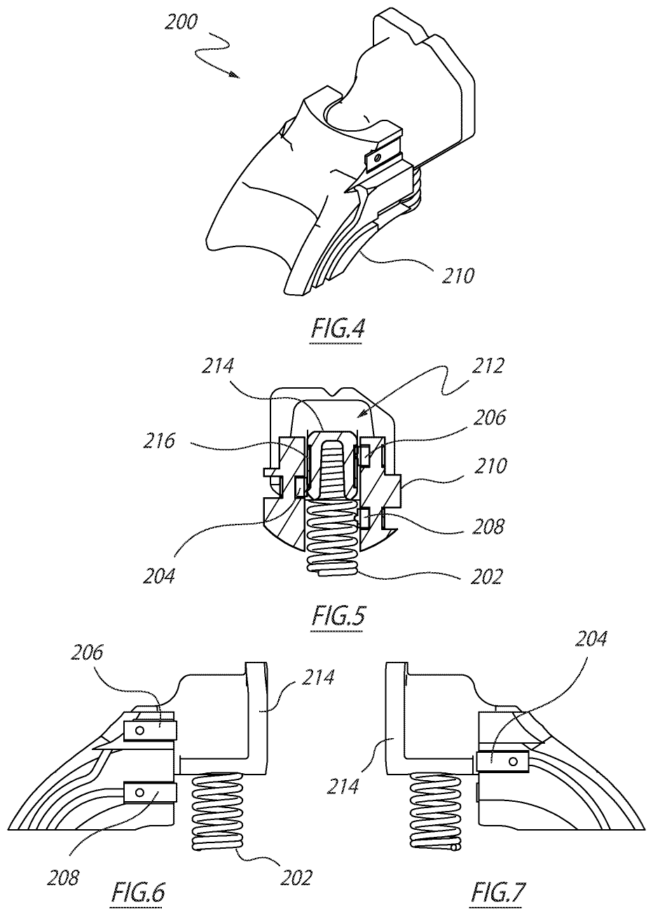

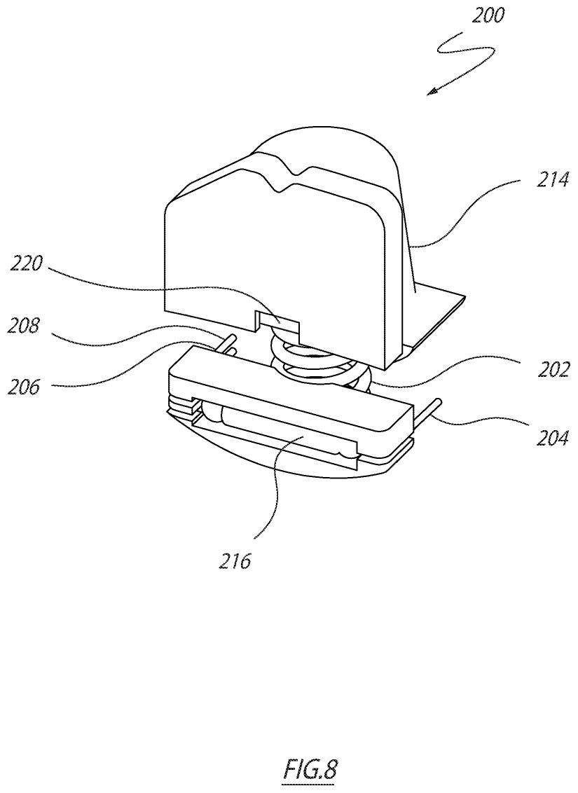

As shown in FIG. 3, the switch 200 is preferably located at an upper end of a handle 105 of the vessel 104. Moving now to FIGS. 4 to 7, which show a first embodiment of the switch 200. In this embodiment, the switch 200 includes a body 210 having a channel 212. On one side of the channel 212, the switch 200 has the common terminal 204, on another side of the channel 212 the switch 200 has the first terminal 206 and the second terminal 208 separated in a first direction by a first distance. Movably located in the channel 212 is the actuator 214. The actuator 214 is movable along the first direction and includes a contact surface 216 adapted to bear against either side of the channel 212 so as to establish contact with the terminals 204, 206, 208. The bias element 202 urges the actuator to the first state, shown in FIG. 5. In this state, the contact surface 216 establishes an electrical contact between the common terminal 204 and the first terminal 206. When the actuator 214 is moved, or depressed, to the second state (not shown), the contact surface 216 establishes an electrical contact between the common terminal 204 and the second terminal 208. The length of the contact surface 216 in the first direction is less than the first distance between the first terminal 206 and the second terminal 208, so that a connection between the first terminal 206 and the second terminal 208 is not possible.

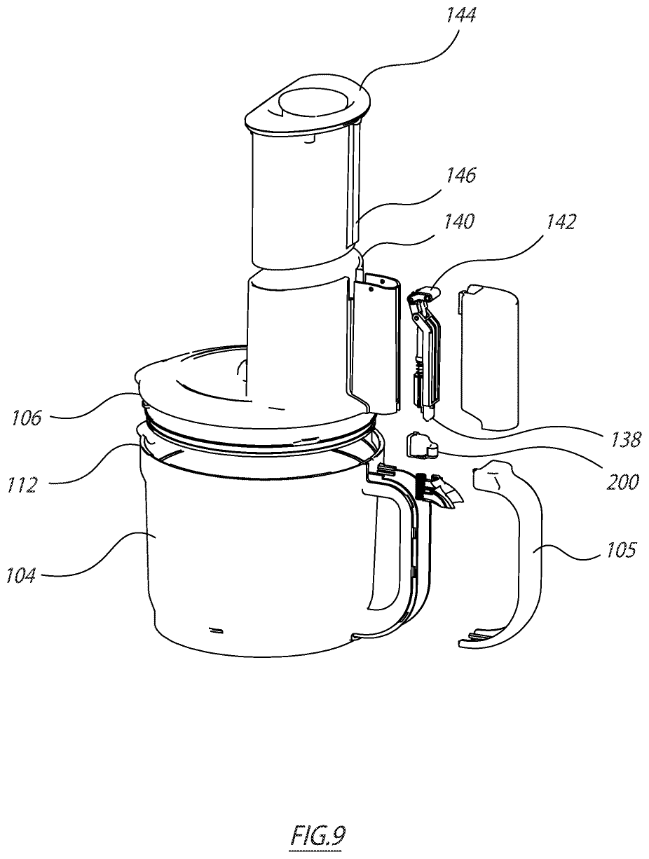

Moving now to FIG. 8, which shows a second embodiment of the switch 200. In this embodiment, the actuator 214 includes a ferromagnetic reed 216 that establishes a contact between the common terminal 204 and the first terminal 206. The actuator 214 also includes a button 218 including a magnet 220 biased by the bias member 202 to be distanced from the reed 216. When the button 218 is moved toward the reed 216 to the second state, the magnet 220 attracts the reed 216, thereby establishing an electrical connection between the common terminal 204 and the second terminal 208.

Irrespective of the switch 200 used, the lid 106 may include a cam 138 that is engageable with the switch 200 to move the switch 200 to the second state when the lid 106 is coupled with the rim 112.

Moving now to FIG. 9, which shows an embodiment of the food processor 100 that includes a feed tube 140. The feed tube 140 includes a linkage 142 that is moveable between a free position, towards which it is biased, and an engaged position. In the engaged position, the linkage 142 is configured to move the switch 200 to the second state, for example by pressing downward on the switch 200. The food processor 100 further includes a pusher device 144 configured to be operable inside the feed tube 140, for example to push food down the feed tube 140 into the space 114 for processing by the mechanism 118. The pusher device 144 includes a pusher cam 146 that is engageable with the linkage 142 to move the linkage 142 to the engaged position when the pusher device 144 is located in the feed tube 140, preferably when the pusher device 144 is located a certain distance inside the feed tube 140. Thus, when the pusher device 144 is located in the feed tube 140, the linkage 142 moves the switch to the second state, causing operation of the mechanism 118.

Advantages of the food processor 100 will now be discussed.

The visible indicator 130 that indicates that power is being transmitted from the transmitter coil 122 to the receiver coil 124, but that the mechanical interlock of switch 200 has not been completed, reduces user error when handling the food processor 100. The use of the illumination device 132 improves the aesthetic appearance of the food processor 100, and allows increased visibility of food as it is processed in the space 114 by the mechanism 118. The use of the linkage 140 allows the reception of a mechanical interlock signal from the pusher device 144 by the circuit 125 located in the vessel 104.

### INTEGERS

100 Food processor
102 base
104 vessel
105 handle
106 lid
108 bottom wall
110 side wall
112 rim
114 space
116 opening
107 lid base
118 mechanism
120 interlock system
122 transmission coil
124 receiver coil
125 circuit
126 optical transmitter
127 filter
128 optical receiver
130 visible indicator
132 illumination device
134 conductive pad
136 connection
138 cam
140 feed tube
142 linkage
144 pusher device
146 pusher cam
200 switch
202 bias element
204 common terminal
206 first terminal
208 second terminal
210 body
212 channel
214 actuator
216 reed
218 button
220 magnet

1. A food processor including:
a base having a mechanism that is operated using electrical power to cause processing of food;
a vessel removably mounted on the base and including a bottom wall, a side wall extending upwardly from the bottom wall to a rim so as to provide a space to receive the food to be processed, with the rim surrounding an opening to the space;
a lid removable coupled to the rim so as to at least partially close the opening; and
an interlock system operatively associated with the mechanism to cause operation of the mechanism, the interlock system including:
a transmission coil mounted in the base and a receiver coil mounted in the vessel, the transmission and receiver coils being configured to allow inductive transmission of power from the transmission coil to the receiver coil;
a switch located on the vessel, operable between a first state and a second state, the switch being biased toward the first state; and
an optical transmitter in the vessel and an optical receiver in the base, the optical transmitter being adapted to emit an activation signal when the switch is in the second state, and the optical receiver being configured to cause operation of the mechanism when the activation signal is received by the optical receiver.

2. The food processor of claim 1, wherein the food processor further includes a visible indicator adapted to provide a visual indication when the switch is in the first state.

3. The food processor of claim 1, wherein the food processor further includes an illumination device embedded in the vessel, the illumination device being connected to a common contact of the switch such that the illumination device provides an illumination of the vessel irrespective of the state of the switch.

4. The food processor of claim 1, wherein the lid includes a conductive pad, and wherein the optical transmitter is not operable unless the conductive pad of the lid completes a connection when coupled to the rim.

5. The food processor of claim 1, wherein the lid includes a cam that is engageable with the switch to move the switch to the second state when the lid is coupled to the rim.

6. The food processor of claim 1, wherein the lid includes a feed tube having a linkage that is moveable between a free position and an engaged position, wherein, in the engaged position, the linkage moves the switch to the second state, and
wherein the food processor further includes a pusher device configured to be operable inside the feed tube, the pusher device including a pusher cam that is engageable with the linkage to move the linkage to the engaged position when the pusher device is located in the feed tube, and thereby move the switch to the second state.

7. The food processor of claim 1, wherein the interlock system further includes a filter between the optical transmitter and the optical receiver, the filter being adapted to filter electromagnetic radiation received by the optical receiver such that wavelengths substantially different to those emitted by the optical transmitter are attenuated.

8. The food processor of claim 7, wherein the filter is located in the base.

9. The food processor of claim 7, wherein the filter attenuates wavelengths outside of the range of 900 nm to 980 nm.
